(19) United States
(12) Patent Application Publication
(10) Pub. No.: US 2026/0182019 A1
(43) Pub. Date: Jun. 25, 2026

(54) CMOS TECHNOLOGY USING NMOS TRANSISTOR WITH OXIDE CHANNEL AND PMOS TRANSISTOR WITH NON-OXIDE CHANNEL

(71) Applicant: Intel Corporation, Santa Clara, CA (US)

(72) Inventors: Rachel A. Steinhardt, Beaverton, OR (US); Kevin P. O'Brien, Portland, OR (US); Punyashloka Debashis, Hillsboro, OR (US); Pratyush P. Buragohain, Hillsboro, OR (US); John J. Plombon, Portland, OR (US); Tristan A. Tronic, Aloha, OR (US); Shane Harlson, Beaverton, OR (US); Arnab Sen Gupta, Hillsboro, OR (US); Dominique A. Adams, Portland, OR (US); Carly Rogan, North Plains, OR (US); Raseong Kim, Portland, OR (US); Hojoon Ryu, Hillsboro, OR (US); Karam Cho, Hillsboro, OR (US); Suehyun Park, Portland, OR (US); Scott B. Clendenning, Portland, OR (US); Matthew V. Metz, Portland, OR (US); Marko Radosavljevic, Portland, OR (US); Ian Alexander Young, Olympia, WA (US); I-Cheng Tung, Hillsboro, OR (US)

(73) Assignee: Intel Corporation, Santa Clara, CA (US)

(21) Appl. No.: 19/000,055

(22) Filed: Dec. 23, 2024

(51) Int. Cl. H10D 84/85; H10D 30/00; H10D 30/01; H10D 30/47; H10D 30/69; H10D 62/10; H10D 62/80; H10D 84/01; H10D 84/08

(52) U.S. Cl. CPC H10D 84/856; H10D 30/017; H10D 30/0191; H10D 30/0415; H10D 30/481; H10D 30/502; H10D 30/701; H10D 62/121; H10D 62/881; H10D 84/0167; H10D 84/08; H10D 84/851

(57) ABSTRACT

Complementary metal-oxide-semiconductor (CMOS) technology using n-type transistors with oxide semiconductor channels and p-type transistors with non-oxide semiconductor channels, and methods of forming the same, are disclosed herein. In one example, a semiconductor device includes a first semiconductor structure and a second semiconductor structure. The first semiconductor structure includes an n-type channel with an oxide semiconductor, and the second semiconductor structure includes a p-type channel with a non-oxide semiconductor. The second semiconductor structure is electrically coupled to the first semiconductor structure.

### BACKGROUND

CMOS technology, which uses complementary p-type and n-type metal-oxide-semiconductor (PMOS, NMOS) field-effect transistors (FETs) to implement digital logic, is present in virtually all modern electronic devices. While conventional PMOS and NMOS transistors use silicon as their semiconductor, oxide semiconductors are emerging as a promising alternative to silicon in some transistor configurations. Implementing CMOS circuitry using oxide semiconductors can be challenging, however, as PMOS transistors typically have much lower performance than their NMOS counterparts when oxide semiconductors are used.

### BRIEF DESCRIPTION OF THE DRAWINGS

FIGS. 1A-C illustrate a CMOS device with an oxide channel for NMOS and a non-oxide channel for PMOS in separate stacks.

FIGS. 2A-C illustrate another CMOS device with an oxide channel for NMOS and a non-oxide channel for PMOS in separate stacks.

FIGS. 3A-D illustrate a process flow for forming a CMOS device with oxide and non-oxide channels for NMOS and PMOS in separate stacks.

FIGS. 4A-F illustrate another process flow for forming a CMOS device with oxide and non-oxide channels for NMOS and PMOS in separate stacks.

FIGS. 5A-B illustrate a CMOS device with an oxide channel for NMOS and a non-oxide channel for PMOS in the same stack.

FIGS. 6A-B illustrate another CMOS device with an oxide channel for NMOS and a non-oxide channel for PMOS in the same stack.

FIG. 7 illustrates a top view of a wafer and dies that may be included in a microelectronic assembly.

FIG. 8 illustrates a cross-sectional side view of an integrated circuit device that may be included in a microelectronic assembly.

FIGS. 9A-D illustrate perspective views of example planar, FinFET, gate-all-around, and stacked gate-all-around transistors.

FIG. 10 illustrates a cross-sectional side view of an integrated circuit device assembly that may include a microelectronic assembly.

FIG. 11 illustrates a block diagram of an example electrical device that may include a microelectronic assembly.

### DETAILED DESCRIPTION

CMOS technology, which uses complementary p-type and n-type metal-oxide- semiconductor (PMOS, NMOS) transistors to implement digital logic, is present in virtually all modern electronic devices. While conventional PMOS and NMOS transistors use silicon as their semiconductor, oxide semiconductors are emerging as a promising alternative for new transistor configurations, such as ferroelectric field-effect transistors (FeFETs) (e.g., where the gate oxide is a ferroelectric material that may be chemically unstable with silicon) and backend transistors (e.g., which may be subject to strict thermal constraints that are unsuitable for processing silicon).

In particular, FeFETs use a ferroelectric material as the gate dielectric or gate oxide, which enables the flow of current through the transistor to be controlled by the polarization state of the ferroelectric material. For example, by applying a positive or negative voltage to the gate, the ferroelectric layer is polarized in one direction or the other, and the resulting electric field induces a conductive or resistive state in the channel to allow or disallow the flow of current. In this manner, FeFETs maintain their state even after the applied voltage is removed, as the ferroelectric layer retains the polarization state induced by the applied voltage. In FeFETs, however, the ferroelectric material is often an oxide that may not be chemically stable with silicon. As a result, in some cases, FeFETs may be implemented with oxide semiconductors in the channel region instead of silicon to avoid the chemical instability between the ferroelectric and silicon.

Oxide semiconductors are also suitable for backend transistors, which are formed during back-end-of-line (BEOL) processing rather than front-end-of-line (FEOL) processing. For example, traditional frontend transistors are typically formed on a silicon substrate during initial stages of processing, while backend transistors are typically formed within interconnect layers above the substrate during later stages of processing. Moreover, BEOL processes are typically subject to strict thermal constraints to avoid damaging the existing circuitry formed during FEOL processing. Oxide semiconductors can be processed at relatively low temperatures, however, which makes them compatible with BEOL processes.

Implementing CMOS circuitry using oxide semiconductors can be challenging, however, as oxide semiconductors typically only perform well as NMOS (n-type) transistors but not as PMOS (p-type) transistors. The lower PMOS performance is due to the band structure of oxide semiconductors along with oxygen vacancies. For example, the valence band maxima of oxide semiconductors tends to have low curvature because of their oxygen 2p orbital character, which leads to low hole mobility, and oxide semiconductors also tend to have oxygen vacancies that act as electron donors, which can effectively cancel hole carriers. As a result, p-type oxide semiconductors tend to have much lower performance than their n-type counterparts, which makes it challenging to implement CMOS circuitry using oxide semiconductors, as both NMOS and PMOS transistors are needed.

Accordingly, this disclosure presents embodiments of CMOS technology implemented using NMOS transistors with oxide semiconductors and PMOS transistors with non-oxide semiconductors. For example, a CMOS device may be implemented using an NMOS transistor with a channel made of an oxide semiconductor (e.g., perovskites or other metal oxides) and a PMOS transistor with a channel made of a conventional non-oxide semiconductor (e.g., group IV or group III-V semiconductors). In some embodiments, the oxide semiconductor may be a perovskite such as barium stannate (BaSnO₃/BSO) or strontium stannate (SrSnO₃) doped with lanthanum (La) or another lanthanide, or another metal oxide compound such as indium tin oxide (InSnO/ITO) or indium gallium zinc oxide (InGaZnO/IGZO)). Moreover, the conventional non-oxide semiconductor may be a group IV semiconductor such as silicon (Si), germanium (Ge), or silicon germanium (SiGe), or a group III-V semiconductor such as gallium nitride (GaN), gallium arsenide (GaAs), or indium phosphide (InP).

The described technology generally covers the combination of oxide and conventional (non-oxide) semiconductors in transistors and other semiconductor devices. In some embodiments, for example, NMOS and PMOS transistors may be integrated in a CMOS device as ribbonFET transistors in separate stacks (e.g., side by side, as shown in CMOS devices 100, 200) or in the same stack (e.g., one on top of the other, as shown in CMOS devices 500, 600). Moreover, in some embodiments, the NMOS and/or PMOS transistors may be FeFETs or backend transistors.

The described embodiments may provide various advantages. In particular, the described embodiments enable the use of oxide semiconductors in CMOS technology without the downside of poor PMOS performance. In addition, the use of oxide semiconductors enables transistor configurations where conventional semiconductor materials (e.g., Si, Ge, SiGe, GaN) may be inadequate, such as FeFETs and backend transistors, among other examples.

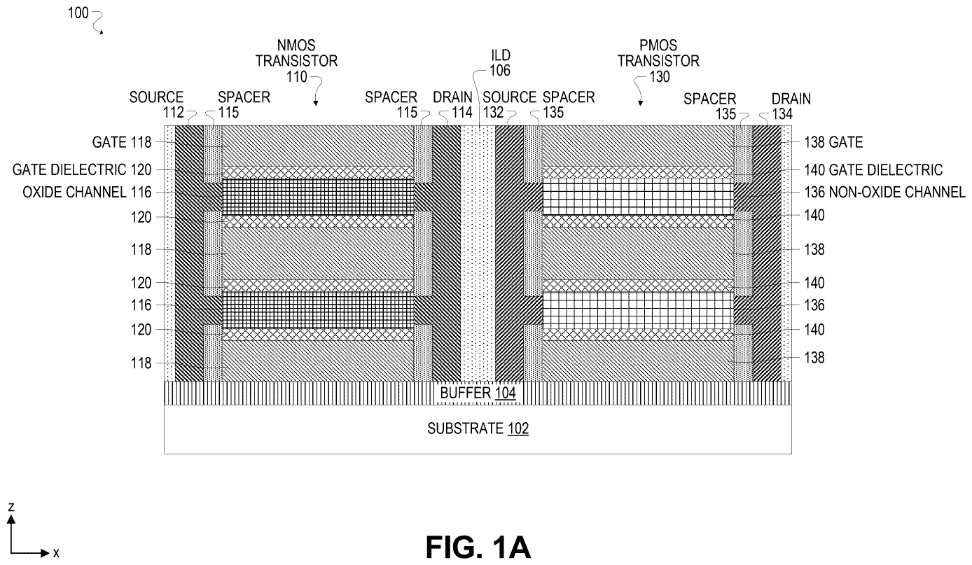

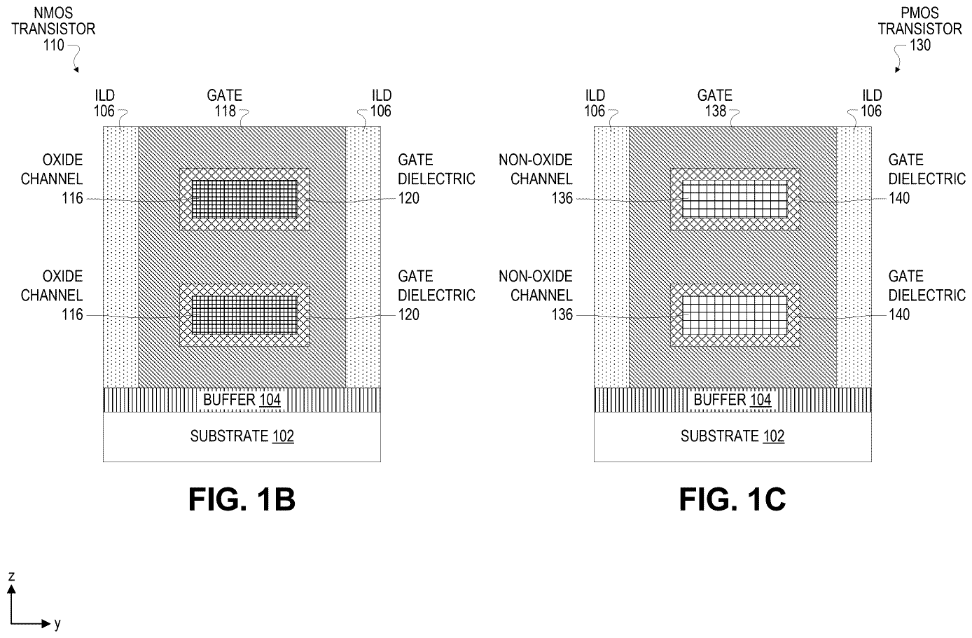

FIGS. 1A-C illustrate a CMOS device 100 with an oxide channel 116 for NMOS and a non-oxide channel 130 for PMOS in separate stacks. In particular, FIG. 1A shows a cross-section (x-z plane) view of a CMOS device 100 with an NMOS transistor 110 and a PMOS transistor 130, and FIG. 1B and FIG. 1C show cross-section (y-z plane) views of the NMOS transistor 110 and the PMOS transistor 130, respectively, in a transverse plane.

In the illustrated embodiment, the CMOS device 100 includes an NMOS transistor 110 and a PMOS transistor 130, which are implemented as ribbon field-effect transistors (ribbonFETs), where the respective ribbonFETs 110, 130 are implemented in separate stacks. Moreover, the NMOS and PMOS transistors 110, 130 use a combination of oxide and non-oxide semiconductors in the channel region. In particular, the NMOS transistor 110 includes an n-type channel 116 made of an oxide semiconductor (e.g., perovskites or other metal oxides), while the PMOS transistor 130 includes a p-type channel 136 made of a conventional non-oxide semiconductor (e.g., group IV or group III-V semiconductors).

In some embodiments, for example, the n-type oxide channel 116 may be made of a perovskite, such as barium stannate (BaSnO₃/BSO) or strontium stannate (SrSnO₃), doped lightly with lanthanum (La) or another lanthanide. Alternatively, the n-type oxide channel 116 may be made of another metal oxide compound, such as indium tin oxide (InSnO/ITO), indium gallium zinc oxide (InGaZnO/IGZO), or another indium oxide (e.g., lightly doped with lanthanum (La) or another lanthanide).

Moreover, in some embodiments, the p-type non-oxide channel 136 may be made of a group IV semiconductor, such as silicon (Si), germanium (Ge), or silicon germanium (SiGe). Alternatively, the p-type non-oxide channel 136 may be made of a group III-V semiconductor, such as gallium nitride (GaN), aluminum gallium nitride (AlGaN), gallium arsenide (GaAs), aluminum gallium arsenide (AlGaAs), indium gallium arsenide (InGaAs), or indium phosphide (InP).

In this manner, CMOS device 100 includes an NMOS transistor 110 with an oxide semiconductor channel 116 and a PMOS transistor 130 with a conventional (e.g., group IV or group III-V) non-oxide semiconductor channel 136. Thus, CMOS device 100 leverages oxide semiconductors only for NMOS, which enables CMOS logic to be implemented using oxide semiconductors without the downside of poor PMOS performance. In particular, the NMOS and PMOS transistors 110, 130 may be electrically coupled via an interconnect to implement CMOS logic. In some embodiments, for example, the source 132 of the PMOS transistor 130 may be connected to a voltage source (V_{DD}), the source 112 of the NMOS transistor 110 may be connected to ground (GND), the gates 118, 138 of the NMOS/PMOS transistors 110, 130 may be connected to the same input signal trace, and the drains 114, 134 of the NMOS/PMOS transistors 110, 130 may be connected to the same output signal trace.

In the illustrated embodiment, the transistors 110, 130 are supported by a substrate 102 and a buffer layer 104. The buffer layer 104 may serve as a template for other layers on the substrate 102. For example, some oxide semiconductors (e.g., perovskites) may be chemically unstable with silicon. Thus, if the substrate 102 includes silicon, the buffer layer 104 may include a material that is chemically stable with the oxide semiconductor used in the oxide channel 116. In some embodiments, for example, the buffer layer 104 may include strontium titanate (SrTiO₃), which can be used as a template for growing other perovskite oxide semiconductors. In other embodiments, the buffer layer 104 may include other materials depending on the material composition of the CMOS device 100.

Each transistor 110, 130 includes source 112, 132 and drain 114, 134 regions, a gate layer 118, 138, gate spacers 115, 135, a gate dielectric 120, 140, and one or more channel nanoribbons 116, 136.

The source 112, 132 and drain 114, 134 are disposed at, and coupled to, opposite ends of the channel nanoribbons 116, 136. In the illustrated embodiment, the transistors 110, 130 are symmetric, and there is no functional distinction between the source region 112, 132 and the drain region 114, 134.

The channel nanoribbons 116, 136 are semiconductor structures extending between the source 112, 132 and drain 114, 134.

The gate spacers 115, 135 are disposed between the gate 118, 138 and the source 112, 132/drain 114, 134 regions. In this manner, the gate spacers 115, 135 serve as dielectric sidewalls on the gate 118, 138 to create separation between the gate 118, 138 and the source 112, 132/drain 114, 134 regions.

The gate 118, 138 and the gate dielectric 120, 140 are disposed over or around the channel nanoribbons 116, 136. In the illustrated embodiment, the gate 118, 138 and the gate dielectric 120, 140 surround the channel nanoribbons 116, 136 on all sides (e.g., as shown in FIG. 1B and FIG. 1C), which is referred to as a gate-all-around (GAA) transistor design. In other embodiments, however, other transistor designs may be used, such as a bi-gate design where the gate 118, 138 and the gate dielectric 120, 140 surround the channel nanoribbons 116, 136 on two sides (e.g., top and bottom sides), or a tri-gate design where the gate 118, 138 and the gate dielectric 120, 140 surround the channel nanoribbons 116, 136 on three sides (e.g., top, left, and right sides).

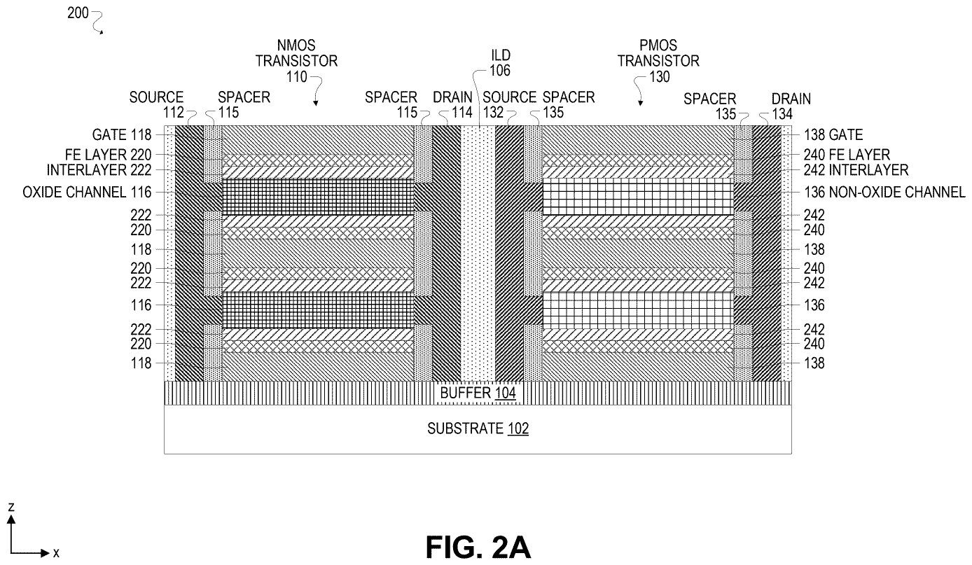

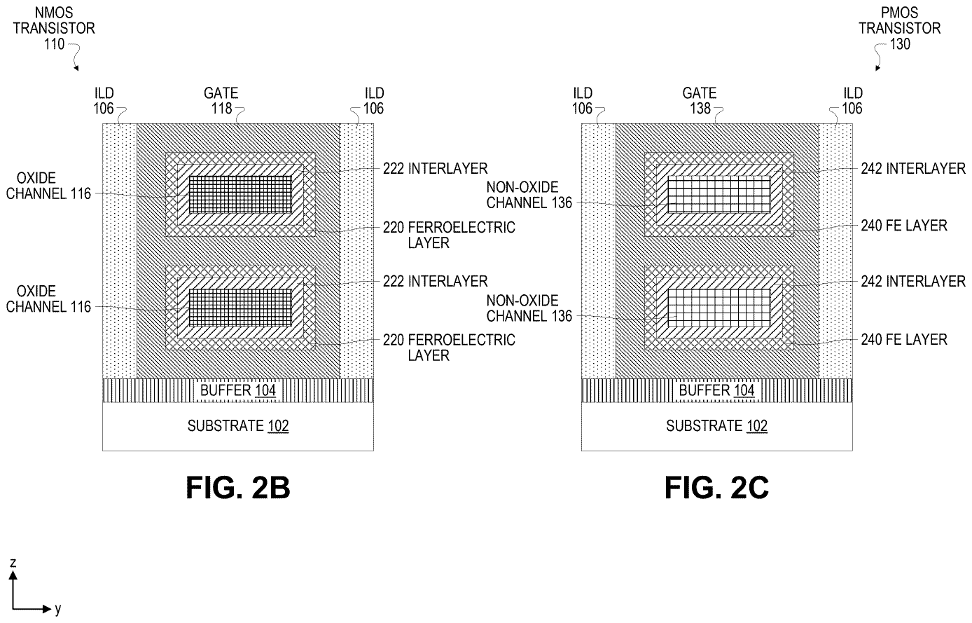

In some embodiments, the gate dielectric 120, 140 may include a ferroelectric layer and/or an oxide interlayer, similar to the ferroelectric layer 220, 240 and the oxide interlayer 222, 242 in CMOS device 200 of FIGS. 2A-C.

The remaining areas are filled with one or more inter-layer dielectrics (ILDs) 106.

In the illustrated embodiment, the transistors 110, 120 are formed over a silicon substrate 102 during front-end-of-line (FEOL) processing. In other embodiments, however, the NMOS and/or PMOS transistors 110, 120 may be backend transistors formed during back-end-of-line (BEOL) processing (e.g., above other silicon transistors formed during FEOL processing). For example, when implemented as backend transistors 110, 130, the stack may include a silicon substrate 102 with other frontend silicon transistors and metal interconnect layers over the frontend transistors, followed by the buffer layer 104 and the transistor stacks 110, 120 shown in CMOS device 100.

In use, a voltage can be applied to the gate 118, 138, which causes an electric field to be applied to the gate dielectric 120, 140 and to the channel nanoribbons 116, 136. The electric field can change the conductivity of the channel 116, 136, turning the ribbonFETs 110, 130 on or off.

The substrate 102 may be made of any suitable material, including, without limitation, silicon, silicon oxide, gallium nitride, a perovskite, strontium titanium oxide, etc.

The buffer layer 104 may be made of any suitable material on which the various layers of CMOS device 100 are grown. In some embodiments, the buffer layer 104 may be lattice matched to the lattice parameter of various layers such as the oxide semiconductor channel 116. For example, the buffer layer 104 may be strontium titanate (SrTiO₃ (STO)).

The source 112 and drain 114 of the NMOS transistor 110 may be made of any suitable material. In some embodiments, the source 112 and drain 114 may be made of a similar material as the channel 116, but with a higher dopant concentration. For example, if the channel 116 includes barium stannate (BaSnO₃) or strontium stannate (SrSnO₃) doped with a relatively low concentration of lanthanum (La), the source 112 and drain 114 may include barium stannate (BaSnO₃) or strontium stannate (SrSnO₃) doped with a relatively high concentration of lanthanum (La). Alternatively, the source 112 and drain 114 may be made of a material that makes good contact with the oxide semiconductor in the channel 116. For example, if the channel 116 includes barium stannate (BaSnO₃) or strontium stannate (SrSnO₃), the source 112 and drain 114 may include another metal that makes good contact with barium stannate (BaSnO₃) or strontium stannate (SrSnO₃).

The source 132 and drain 134 of the PMOS transistor 130 may be made of any suitable material. In some embodiments, the source 132 and drain 134 may include silicon.

The n-type channel 116 of the NMOS transistor 110 may be made of any suitable oxide semiconductor material. In some embodiments, the n-type channel 116 may include a perovskite. A perovskite is a material with a crystal structure similar to calcium titanate (CaTiO₃), typically with the chemical formula of ABX₃, where A is a large cation (e.g., an alkaline earth metal such as barium (Br) or strontium (Sr)), B is a smaller cation (e.g., a transition metal such as tin (Sn) or titanium (Ti)), and X is an anion (e.g., oxygen). In some embodiments, the perovskite in the n-type channel 116 may be barium stannate (BaSnO₃ (BSO)), strontium stannate (SrSnO₃), barium strontium stannate ((BaSr)SnO₃), or strontium titanate (SrTiO₃). In some embodiments, the perovskite may be lightly doped (e.g., doped with a relatively low dopant concentration) with a lanthanide such as lanthanum (La). For example, the perovskite may include lightly-doped BaSnO₃ (BSO), lightly-doped SrSnO₃, lightly-doped (BaSr)SnO₃, lightly-doped SrTiO₃, or another lightly-doped perovskite material, where the dopant is a lanthanide (e.g., La). In some embodiments, the n-type channel 116 may include another metal oxide semiconductor, such as indium tin oxide (InSnO (ITO)), indium gallium zinc oxide (InGaZnO (IGZO)), or another indium oxide, which may be lightly doped with a lanthanide such as lanthanum (La). Thus, in various embodiments, the n-type channel 116 may be made of material that include elements such as lanthanum (La), barium (Ba), strontium (Sr), tin (Sn), zinc (Zn), titanium (Ti), oxygen (O), indium (In), and/or gallium (Ga)

The p-type channel 136 of the PMOS transistor 130 may be made of any suitable non-oxide semiconductor material. In some embodiments, the p-type channel 136 may include a group IV semiconductor, such as silicon (Si), germanium (Ge), or silicon germanium (SiGe). In some embodiments, the p-type channel 136 may include a group III-V semiconductor, such as gallium nitride (GaN), aluminum gallium nitride (AlGaN), gallium arsenide (GaAs), aluminum gallium arsenide (AlGaAs), indium gallium arsenide (InGaAs), or indium phosphide (InP). In some embodiments, the semiconductor material in the p-type channel 136 may be doped a p-type dopant, such as boron (B). Thus, in various embodiments, the p-type channel 136 may be made of material that include elements such as gallium (Ga), aluminum (Al), indium (In), nitrogen (N), arsenic (As), phosphorus (P), and/or boron (B).

The gate 118, 138 of the NMOS and PMOS transistors 110, 130 may be made of any suitable conductive or metal material.

The gate dielectric 120, 140 may include any suitable dielectric material, such as a high-k dielectric. In some embodiments, the gate dielectric 120, 140 may include hafnium oxide (HfO₂), doped hafnium oxide (doped HfO₂), silicon dioxide (SiO₂), barium stannate (BaSnO₃), strontium stannate (SrSnO₃), strontium titanate (SrTiO₃), lanthanum aluminate (LaAlO₃), barium hafnate (BaHfO₃), barium zirconate (BaZrO₃), strontium zirconate (SrZrO₃), strontium hafnate (SrHfO₃), lanthanum indium oxide (LaInO₃), lanthanum lutetium oxide (LaLuO₃), magnesium oxide (MgO), or a rare-earth scandate (e.g., an oxide combining scandium (Sc) with rare-earth elements such as dysprosium (Dy), terbium (Tb), gadolinium (Gd), europium (Eu), samarium (Sm), neodymium (Nd), praseodymium (Pr), cerium (Ce), lanthanum (La)). Examples of rare-earth scandates include, without limitation, lanthanum scandate (LaScO₃), lanthanum lutetium scandate (La(LuSc)O₃), dysprosium scandate (DyScO₃), terbium scandate (TbScO₃), gadolinium scandate (GdScO₃), europium scandate (EuScO₃), samarium scandate (SmScO₃), neodymium scandate (NdScO₃), praseodymium scandate (PrScO₃), and cerium scandate (CeScO₃).

The gate spacers 115, 135 and the inter-layer dielectrics (ILDs) 106 may be made of any suitable dielectric materials, including, without limitation, silicon oxide (e.g., SiO₂), silicon nitride (SiN), silicon oxynitride (SiON), silicon oxycarbide (SiOC), silicon oxycarbonitride (SiOCN), and/or other low-k dielectrics.

In this disclosure, an oxide semiconductor may refer to a semiconductor material that includes oxygen, while a non-oxide semiconductor may refer to a semiconductor material that does not include oxygen. An oxide semiconductor channel (or oxide channel) may refer to a semiconductor channel that includes an oxide semiconductor, while a non-oxide semiconductor channel (or non-oxide channel) may refer to a semiconductor channel that includes a non-oxide semiconductor material. An oxide transistor may refer to a transistor with an oxide semiconductor channel, and a non-oxide transistor may refer to refers to a transistor with a non-oxide semiconductor channel.

Nanoribbons may be referred to (or implemented) as nanowires or nanosheets.

A group N semiconductor, where N represents one or more groups from the periodic table of elements, refers to a semiconductor material that includes one or more elements from group(s) N of the periodic table. For example, a group IV semiconductor refers to a semiconductor material that includes one or more elements from group IV of the periodic table, while a group III-V semiconductor refers to a semiconductor material that includes one or more elements from each of group III and group V of the periodic table.

It should be appreciated that CMOS device 100 is merely an example embodiment and numerous other embodiments are also within the scope of this disclosure. In various embodiments, for example, certain elements of CMOS device 100 may be modified, replaced, rearranged, omitted, and/or added.

For example, while the transistors 110, 130 are implemented with a ribbonFET and gate-all-around (GAA) transistor design, other transistor designs may be used in other embodiments (e.g., FinFET, planar FET, bi-gate transistors, tri-gate transistors). The CMOS device 100 may include any number of NMOS and PMOS transistors 110, 130. The transistors 110, 130 may include any number of channel nanoribbons 116, 136. In some embodiments, the buffer layer 104 may be omitted. Further, in various embodiments, the materials used in each layer may differ from those described above.

In some embodiments, CMOS device 100 may be used to implement circuitry (e.g., processing circuitry, memory circuitry, storage circuitry, or communication circuitry) in an integrated circuit.

Moreover, the concepts described above for CMOS device 100, including any modifications thereof, also apply to the other embodiments in this disclosure, including CMOS devices 200, 500, 600.

FIGS. 2A-C illustrate another CMOS device 200 with an oxide channel 116 for NMOS and a non-oxide channel 130 for PMOS in separate stacks. In particular, FIG. 2A shows a cross-section (x-z plane) view of CMOS device 200 with NMOS transistor 110 and PMOS transistor 130, and FIG. 2B and FIG. 2C show cross-section (y-z plane) views of NMOS transistor 110 and PMOS transistor 130, respectively, in a transverse plane.

In the illustrated embodiment, CMOS device 200 is similar to CMOS device 100, except the transistors 110, 130 are implemented with a ferroelectric (FE) layer 220, 240 and a dielectric interlayer 222, 242 as the gate dielectric (e.g., instead of gate dielectric 120, 140). In this manner, the transistors 110, 130 may be implemented as ferroelectric field-effect transistors (FeFETs) or negative capacitance field-effect transistors (NC-FETs).

In particular, FeFETs use a ferroelectric material 220, 240 as the gate dielectric or gate oxide, which enables the flow of current through the channel 116, 136 to be controlled by the polarization state of the ferroelectric material 220, 240. For example, by applying a positive or negative voltage to the gate 118, 136, the ferroelectric layer 220, 240 is polarized in one direction or the other, and the resulting electric field induces a conductive or resistive state in the channel 116, 136 to allow or disallow the flow of current. In this manner, the FeFETs maintain their state even after the applied voltage is removed, as the ferroelectric layer 220, 240 retains the polarization state induced by the applied voltage.

NC-FETs utilize the concept of negative capacitance to improve the energy efficiency and performance of traditional field-effect transistors (FETs). In traditional FETs, the positive capacitance between the gate and the channel dictates how much energy is required to switch the transistors on and off. In NC-FETs, a material with negative capacitance (e.g., where polarization of the material decreases as the applied voltage increases) is used as the gate dielectric or gate oxide, such as certain types of ferroelectric materials 220, 240, which reduces switching voltage and power consumption.

In the illustrated embodiment, the interlayer 222, 242 also serves partially as the gate dielectric (e.g., along with the ferroelectric layer 220, 240). In some embodiments, the interlayer 222, 242 may also help with chemical stability, band offset, epitaxial growth, and/or leakage current. For example, the interlayer 222, 242 may improve the chemical stability between the ferroelectric layer 220, 240 and the channel 116, 136, increase band offsets, serve as an epitaxial template, and/or reduce leakage current between the channel 116, 136 and the ferroelectric layer 220, 240 or gate layer 118, 138.

In some embodiments, the interlayer 222, 242 may be omitted from one or both of the NMOS transistor 110 and the PMOS transistor 130 depending on the particular materials used in the implementation.

In the NMOS transistor 110, for example, the interlayer 222 may not be needed to provide chemical stability between the ferroelectric layer 220 and the oxide semiconductor channel 116, as ferroelectric materials are generally chemically stable with oxide semiconductors. Thus, in some embodiments, the interlayer 222 may be omitted from the NMOS transistor 110. In other embodiments, however, the interlayer 222 may nonetheless be included in the NMOS transistor 110 to provide some of the other benefits described above (e.g., increase band offset, reduce leakage).

In the PMOS transistor 130, however, the interlayer 242 may be needed to provide chemical stability between the ferroelectric layer 240 and the non-oxide semiconductor channel 136, as many ferroelectric materials are chemically unstable with conventional semiconductors such as silicon. Thus, in some embodiments, the interlayer 242 may be included in the PMOS transistor 130 to provide chemical stability. In other embodiments, however, the particular ferroelectric material in the ferroelectric layer 240 (e.g., a doped hafnium oxide such as hafnium zirconium oxide) may be chemically stable with the conventional semiconductor in the non-oxide channel 136 (e.g., silicon). As a result, the interlayer 242 may be omitted from the PMOS transistor 130 in some embodiments.

The ferroelectric layer 220, 240 may include any suitable ferroelectric material. In some embodiments, the ferroelectric layer 220, 240 may include barium titanate (BaTiO₃), barium zirconate titanate (Ba(Zr,Ti)O₃), barium calcium titanate ((Ba,Ca)TiO₃), barium strontium titanate ((Ba,Sr)TiO₃), barium calcium zirconate titanate ((Ba,Ca)(Ti,Zr)O₃), barium hafnate titanate (Ba(Hf,Ti)O₃), bismuth ferrite (BiFeO₃), bismuth lanthanum ferrite ((Bi,La)FeO₃), bismuth iron cobalt oxide (Bi(Fe,Co)O₃), lithium niobate (LiNbO₃), potassium niobate (KNbO₃), gadolinium ferrite (GdFeO₃), gadolinium lanthanum ferrite ((Gd,La)FeO₃), hafnium zirconium oxide ((HfZr)O₂), or doped hafnium oxide (doped HfO₂).

The interlayer 222, 242 may include any suitable dielectric. In some embodiments, the interlayer 222, 242 may include any of the materials described above with respect to the gate dielectrics 120, 140.

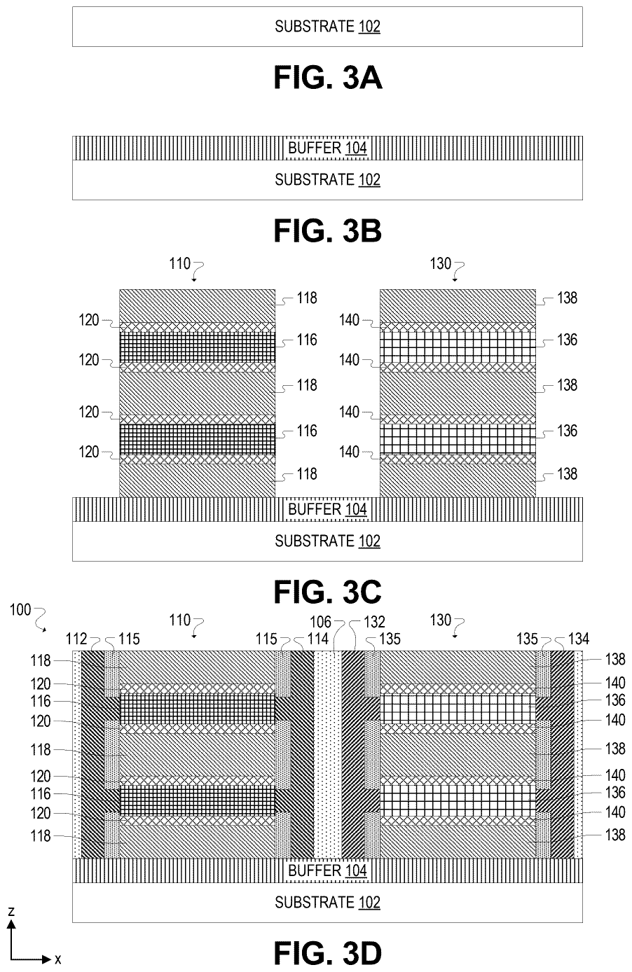

FIGS. 3A-D illustrate a process flow for forming a CMOS device 100 with oxide and non-oxide channels 116, 136 for NMOS and PMOS in separate stacks. In the illustrated example, FIGS. 3A-D show cross-section (x-z plane) views after performing various steps of the process flow. It will be appreciated in light of the present disclosure that the illustrated process flow is only one example methodology for arriving at CMOS device 100.

The steps of the illustrated process flow may be performed using any suitable semiconductor processing techniques. For example, layers may be formed using any suitable techniques, including, without limitation, chemical vapor deposition (CVD), metal-organic chemical vapor deposition (MOCVD), molecular beam epitaxy (MBE), atomic layer deposition (ALD), physical vapor deposition (PVD) (e.g., PVD sputtering), pulsed laser deposition (PLD), layer transfer, and/or ion implantation. Moreover, layer patterning and removal may be performed using any suitable techniques, such as photolithography-based patterning/masking and etching (e.g., dry/wet etching).

In FIG. 3A, a substrate 102 is received. In some embodiments, the substrate 102 may include silicon (Si) (e.g., a silicon wafer).

In FIG. 3B, a buffer layer 104 is formed over the substrate 102. The buffer layer 104 may serve as a template for subsequent layers formed over the substrate 102. For example, some oxide semiconductors (e.g., perovskites) may be chemically unstable with a silicon substrate 102. Thus, in some embodiments, the buffer layer 104 may include a material that is chemically stable with the particular oxide semiconductor used in the oxide channel 116. For example, the buffer layer 104 may include strontium titanate (SrTiO₃), which can be used as a template for growing other perovskite oxides on the silicon substrate 102. In other embodiments, the buffer layer 104 may include other materials depending on the material composition of the CMOS device 100.

In FIG. 3C, separate NMOS and PMOS ribbonFET stacks 110, 130 are formed over the buffer layer 104. In some embodiments, for example, each ribbonFET stack 110, 130 may include channel nanoribbons 116, 136, a gate dielectric 120, 140, and a gate metal 118, 138.

In the NMOS stack 110, the channel nanoribbons 116 may include an oxide semiconductor, such as a perovskite (e.g., BaSnO₃ (BSO) or SrSnO₃ doped with La or another lanthanide) or another metal oxide (e.g., an indium oxide such as InSnO (ITO) or InGaZnO (IGZO)).

In the PMOS stack 130, the channel nanoribbons 136 may include a conventional (e.g., non-oxide) semiconductor, such as a group IV semiconductor (e.g., Si, Ge, SiGe) or a group III-V semiconductor (e.g., GaN, AlGaN, GaAs, AlGaAs, InGaAs, InP).

In the illustrated process flow for CMOS device 100, the gate dielectric 120, 140 may include any suitable dielectric. In another process flow for CMOS device 200, however, the gate dielectric 120, 140 may include a ferroelectric layer 220, 240 and/or an oxide interlayer 222, 242.

In FIG. 3D, gate spacers 115, 135 are formed on opposite sides of the NMOS/PMOS stacks 110, 130, along with source regions 112, 132 and drain regions 114, 134. The gate spacers 115, 135 serve as dielectric sidewalls on the gate 118, 138 to create separation between the gate 118, 138 and the source 112, 132/drain 114, 134 regions. The source 112, 132/drain 114, 134 regions are coupled to opposite ends of the channel nanoribbons 116, 136. The remaining areas are filled with one or more inter-layer dielectrics (ILDs) 106.

The completed CMOS device 100 includes NMOS/PMOS ribbonFETs 110, 130 with a source 112, 132, a drain 114, 134, nanoribbon channels 116, 136, a gate 118, 138, a gate dielectric 120, 140, and gate spacers 115, 135.

At this point, any remaining processing may be performed, such as forming source/drain/gate contacts, ILD filling/planarization, interconnect patterning (e.g., metallization), interconnect bump formation, backside processing, singulation, packaging, etc. For example, in wafer-or panel-level process flows, the completed wafer or panel may be diced to singulate the integrated circuit (IC) dies on the wafer or panel. The singulated IC dies may then be incorporated into an IC package, circuit board, electronic device, system, etc.

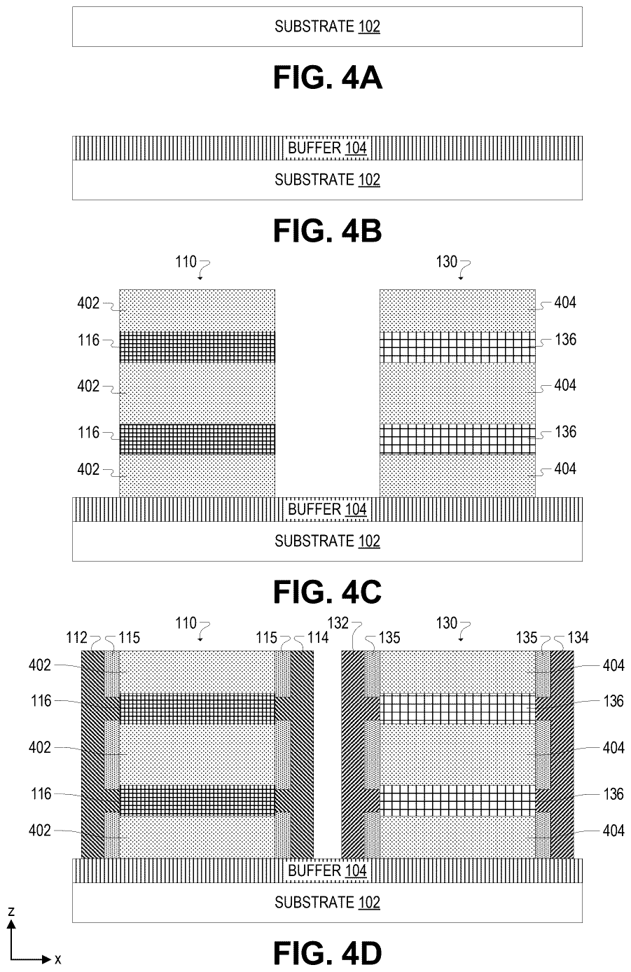

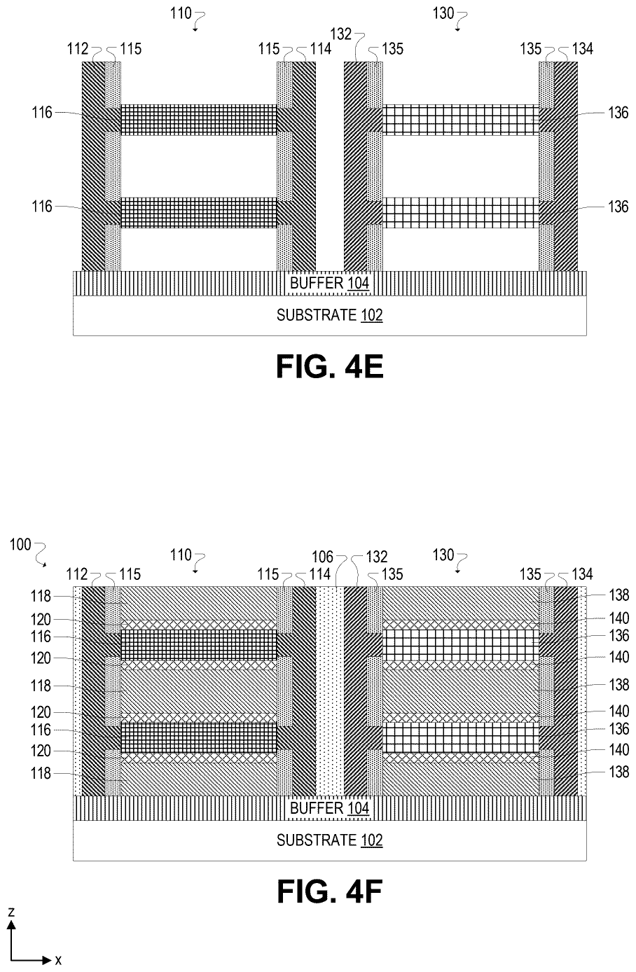

FIGS. 4A-F illustrate another process flow for forming a CMOS device 100 with oxide and non-oxide channels 116, 136 for NMOS and PMOS in separate stacks. In the illustrated example, FIGS. 4A-F show cross-section (x-z plane) views after performing various steps of the process flow. It will be appreciated in light of the present disclosure that the illustrated process flow is only one example methodology for arriving at CMOS device 100.

The steps of the illustrated process flow may be performed using any suitable semiconductor processing techniques, including any of the techniques described above with respect to FIG. 3.

In FIG. 4A, a substrate 102 is received, and in FIG. 4B, a buffer layer 104 is formed over the substrate 102.

In FIG. 4C, separate NMOS/PMOS superlattice stacks 110, 130 are formed over the buffer layer 104, which include alternating semiconductor layers 116, 136 and sacrificial layers 402, 404. In the NMOS stack 110, the semiconductor layers 116 may include an oxide semiconductor, such as a perovskite or another metal oxide. In the PMOS stack 130, the semiconductor layers 136 may include a conventional (e.g., non-oxide) semiconductor, such as a group IV semiconductor or a group III-V semiconductor. This semiconductor layers 116, 136 will serve as the channel nanoribbons of the NMOS/PMOS ribbonFETs 110, 130 once the sacrificial layers 402, 404 are subsequently etched away.

In FIG. 4D, gate spacers 115, 135 are formed on opposite sides of the NMOS/PMOS stacks 110, 130, along with source regions 112, 132 and drain regions 114, 134, which are coupled to opposite ends of the channel nanoribbons 116, 136.

In FIG. 4E, the sacrificial layers 402, 404 are etched away to release the semiconductor layers 116, 136, thus forming the nanoribbon channels 116, 136 of the NMOS/PMOS ribbonFETs 110, 130.

In FIG. 4F, a gate dielectric 120, 140 and a gate 118, 138 are formed over the channel nanoribbons 116, 136 (e.g., with the gate dielectric 120, 140 between the gate 118, 138 and the nanoribbons 116, 136). The remaining areas are filled with one or more inter-layer dielectrics (ILDs) 106.

At this point, the CMOS device 100 may be complete, and any remaining processing may be performed (e.g., the remaining processing described above for the process flow of FIG. 3).

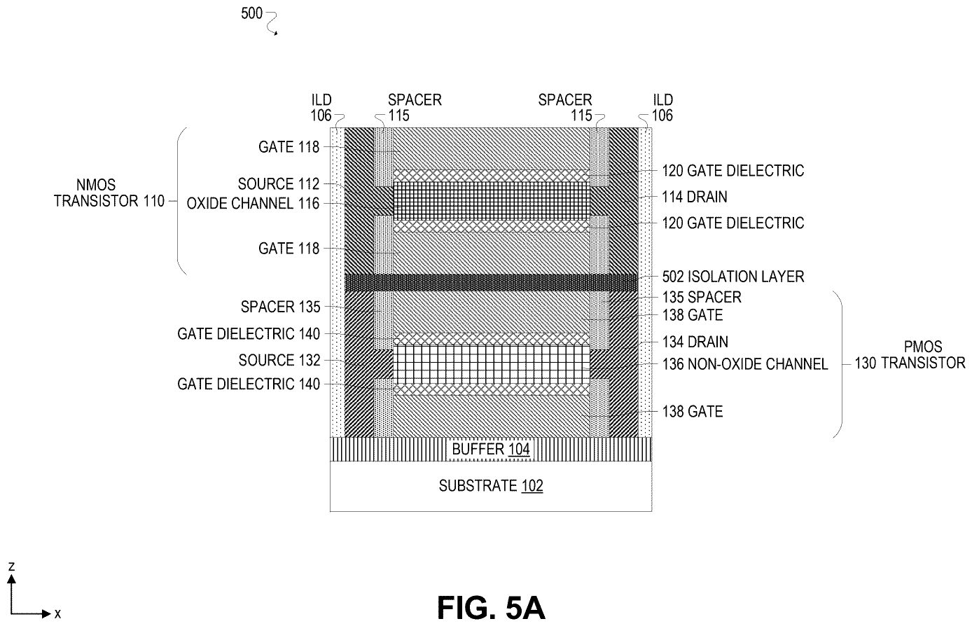

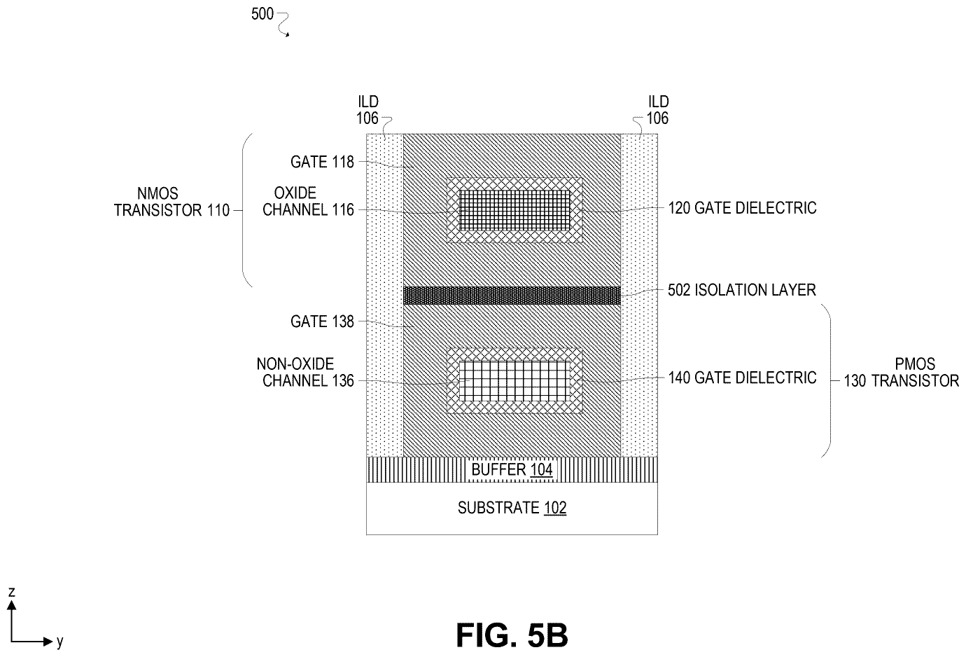

FIGS. 5A-B illustrate a CMOS device 500 with an oxide channel 116 for NMOS and a non-oxide channel 136 for PMOS in the same stack. In particular, FIG. 5A shows a cross-section (x-z plane) view of CMOS device 500, and FIG. 5B shows another cross-section (y-z plane) view of CMOS device 500 in a transverse plane. In the illustrated embodiment, CMOS device 500 is similar to CMOS device 100, except the respective NMOS and PMOS ribbonFETs 110, 130 are implemented in the same stack (e.g., a single stack with one ribbonFET stacked on top of the other) instead of separate stacks, with an isolation layer 502 between them. In some embodiments, CMOS device 500 may be fabricated using a process flow similar to those of FIG. 3 and FIG. 4, except with the ribbonFETs 110, 130 formed in a single stack instead of separate stacks.

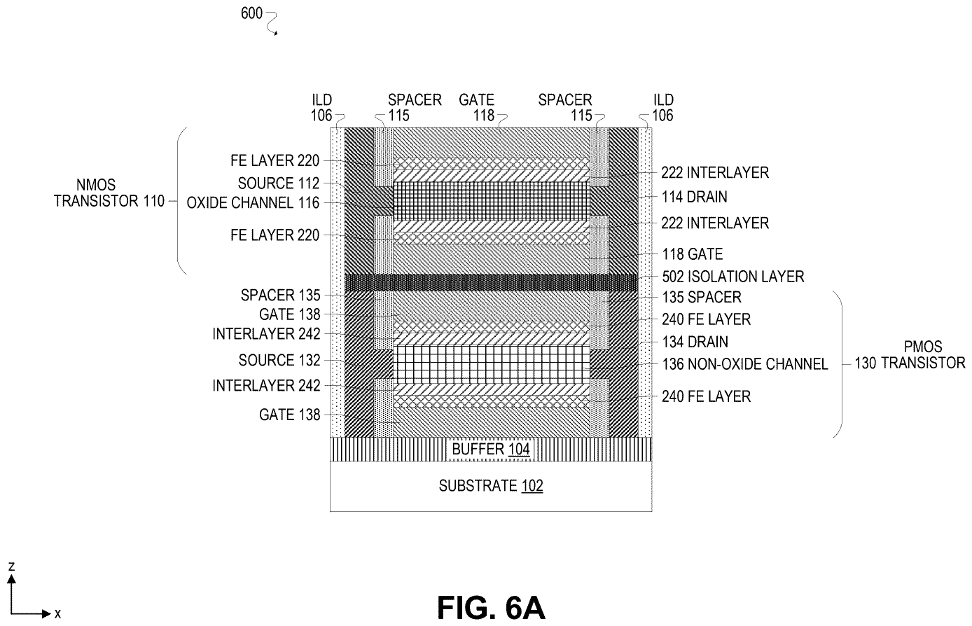

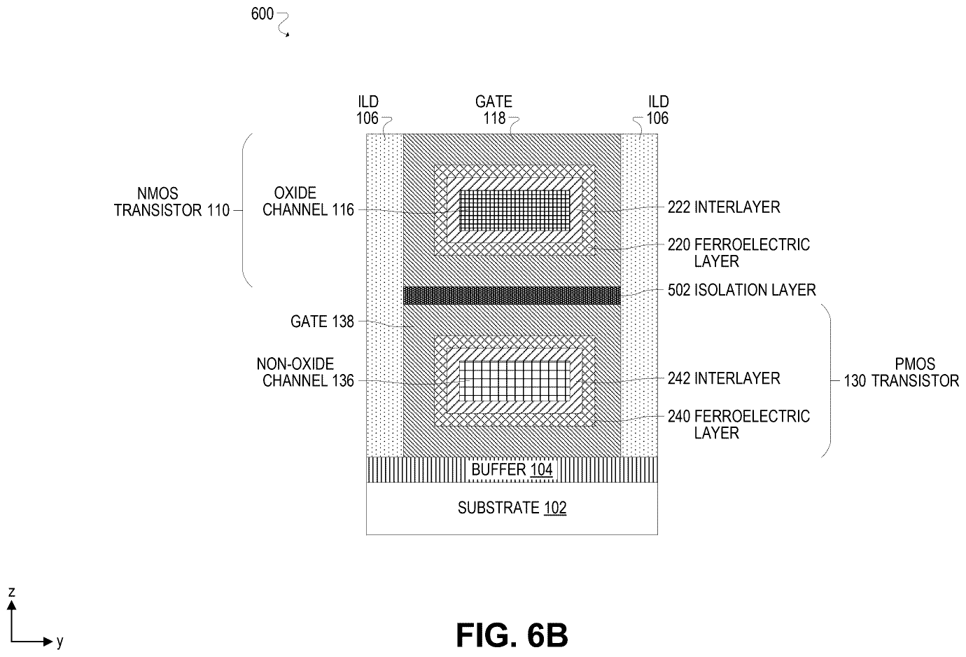

FIGS. 6A-B illustrate another CMOS device 600 with an oxide channel 116 for NMOS and a non-oxide channel 136 for PMOS in the same stack. In particular, FIG. 6A shows a cross-section (x-z plane) view of CMOS device 600, and FIG. 6B shows another cross-section (y-z plane) view of CMOS device 600 in a transverse plane. In the illustrated embodiment, CMOS device 600 is similar to CMOS device 500, except the transistors 110, 130 are implemented with a ferroelectric (FE) layer 220, 240 and a dielectric interlayer 222, 242 as the gate dielectric (e.g., instead of gate dielectric 120, 140), similar to CMOS device 200. In some embodiments, CMOS device 600 may be fabricated using a process flow similar to those of FIG. 3 and FIG. 4, except with the ferroelectric layer 220, 240 and interlayer 222, 242 as the gate dielectric (e.g., instead of gate dielectric 120, 140).

### Example Integrated Circuit Embodiments

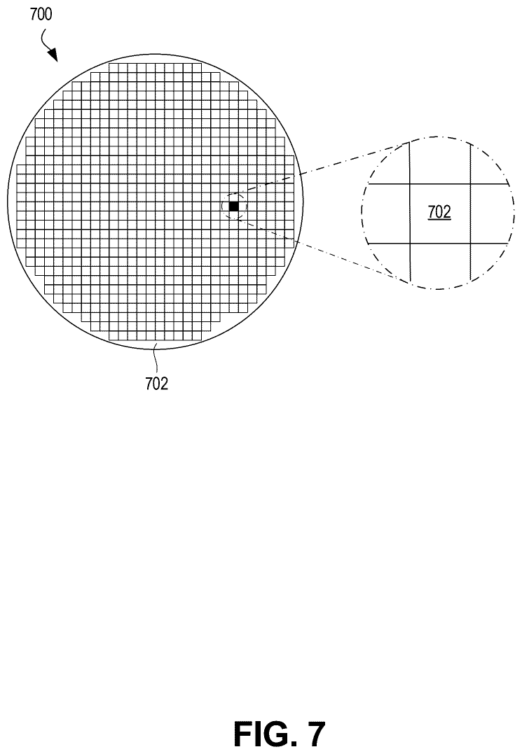

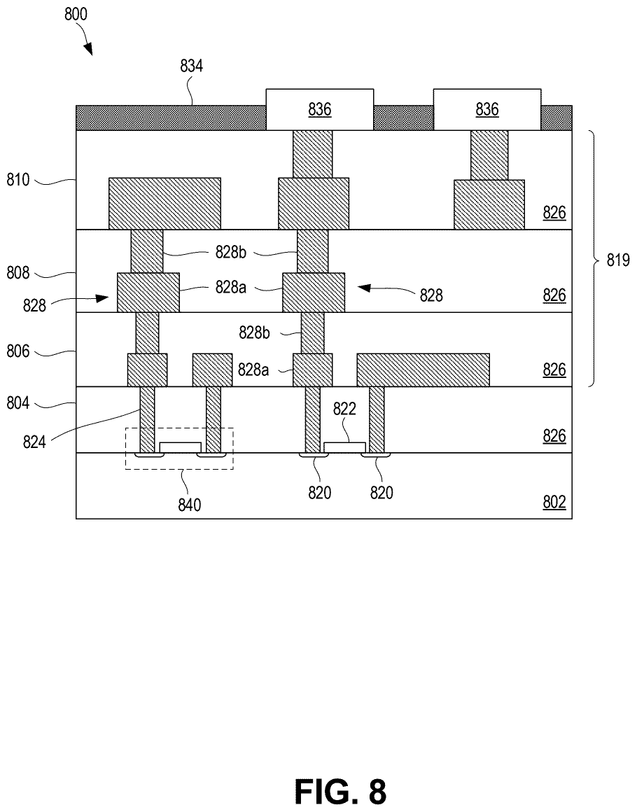

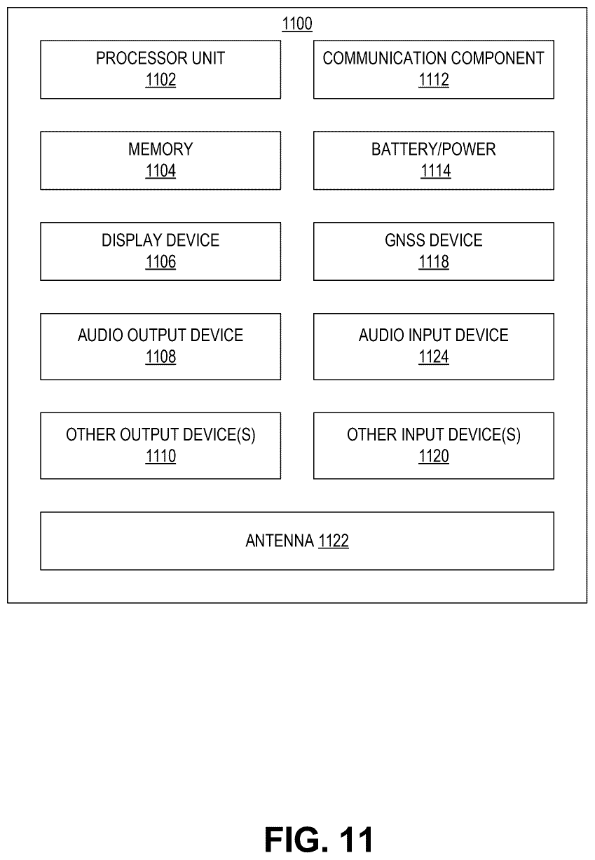

FIG. 7 is a top view of a wafer 700 and dies 702 that may include any of the embodiments disclosed herein. In some embodiments, for example, the dies 702 may include one or more CMOS devices and/or transistors with oxide and non-oxide channels (e.g., CMOS device 100, 200, 500, 600, NMOS transistor 110, PMOS transistor 130). The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may include any of the embodiments disclosed herein (e.g., CMOS device 100, 200, 500, 600, NMOS transistor 110, PMOS transistor 130). One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

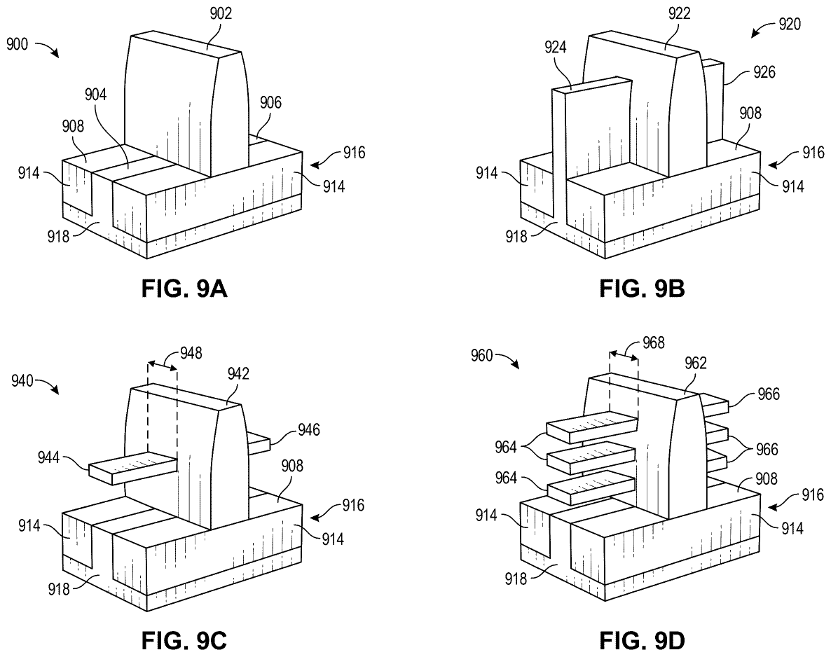

FIGS. 9A-D are simplified perspective views of example planar, FinFET, gate-all-around, and stacked gate-all-around transistors. In some embodiments, these transistors may be implemented with oxide and non-oxide channels for PMOS circuitry (e.g., similar to transistors 110, 130, CMOS devices 100, 200, 500, 600). The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 918. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 928.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorus, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorus. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as any of the conductive contacts described throughout this disclosure.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836. These additional conductive contacts may serve as any of the conductive contacts described throughout this disclosure.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. These additional conductive contacts may serve as any of the conductive contacts described throughout this disclosure. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

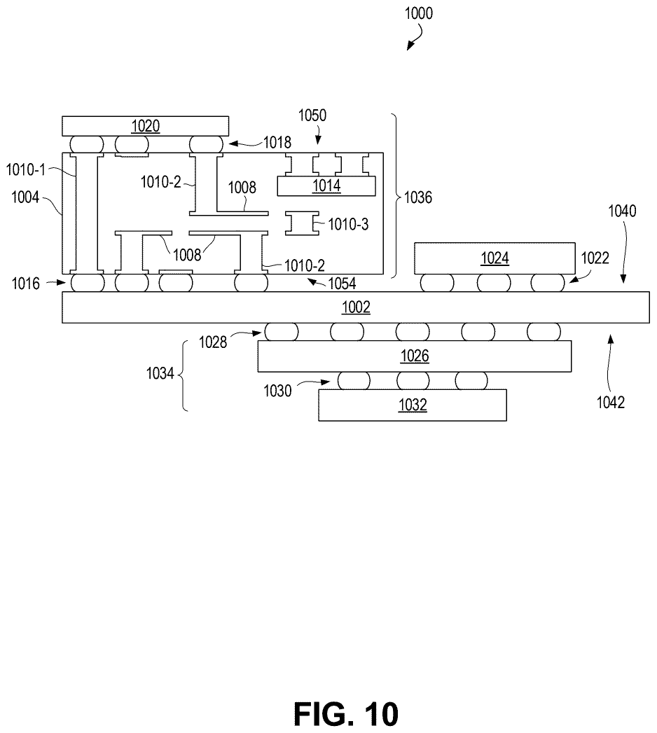

FIG. 10 is a cross-sectional side view of an integrated circuit device assembly 1000 that may include any of the embodiments disclosed herein. In some embodiments, for example, the embedded devices 1014 and/or IC components 1020, 1024, 1026, 1032 of the integrated circuit device assembly 1000 may include CMOS circuitry and/or transistors with oxide and non-oxide channels (e.g., CMOS devices 100, 200, 500, 600, transistors 110, 130).

In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more of the CMOS devices 100, 200, 500, 600, transistors 110, 130, integrated circuit device assemblies 1000, integrated circuit components 1020, integrated circuit devices 800, or integrated circuit dies 702 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1(L1 ), Level 2(L2 ), Level 3(L3 ), Level 4(L4 ), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include other output device(s) 1110 (or corresponding interface circuitry, as discussed above). Examples of the other output device(s) 1110 may include an audio codec, a video codec, a printer, a wired or wireless transmitter for providing information to other devices, or an additional storage device.

The electrical device 1100 may include other input device(s) 1120 (or corresponding interface circuitry, as discussed above). Examples of the other input device(s) 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

The terms “substantially,” “close,” “approximately,” “near,” and “about” may refer to being within +/−10% of a target value unless otherwise specified.

Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In some embodiments, the phrase “A is located on B” or the phrase “A is adjacent to B” means that at least a part of A is in direct physical contact or indirect physical contact (having one or more other features between A and B) with at least a part of B. Moreover, the phrase “B is between A and C” means that at least part of B is in or along a space separating A and C and that at least part of B is in direct or indirect physical contact with A and C.

The terms “coupled” and “connected” may refer to either a direct or indirect connection, such as a direct electrical, mechanical, or magnetic connection, or an indirect connection through one or more passive or active intermediary elements, components, or devices.

The phrases “in an embodiment,” “according to some embodiments,” “in accordance with embodiments,” “in embodiments,” and the like may each refer to one or more of the same or different embodiments.

The terms “comprises,” “comprising,” “includes,” “including,” “having” and the like specify the presence of the stated elements (e.g., features, components, materials, steps, operations) but do not preclude the presence or addition of one or more other elements.

The phrase “and/or” as used herein refers to and encompasses any and all possible combinations of one or more of the associated listed items.

The singular forms “a,” “an,” and “the” are intended to include the plural forms as well, unless the context clearly indicates otherwise. For example, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn, and Ni.

The terms “circuit” or “circuitry,” as used in any embodiment herein may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

For purposes of some embodiments, the transistors in various circuits and logic blocks described herein may be metal oxide semiconductor (MOS) transistors or their derivatives, where the MOS transistors include drain, source, gate, and/or bulk terminals. The transistors and/or the MOS transistor derivatives also include Bi-Gate, Tri-Gate, and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals are identical terminals and may be used interchangeably herein. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.). Moreover, in some embodiments, spintronic logic devices (e.g., magnetoelectric spin-orbit (MESO) logic devices) may be used in addition to, or as an alternative to, MOS transistors.

In the foregoing description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, may not be described in detail in order to avoid unnecessarily obscuring embodiments of the present disclosure.

It is to be appreciated that the layers and materials described above are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted above may be fabricated on underlying lower level back end of line (BEOL) interconnect layers.

Embodiments disclosed herein may be used to manufacture a wide variety of different types of integrated circuits and/or microelectronic devices. Examples of such integrated circuits include, but are not limited to, processors, chipset components, graphics processors, digital signal processors, microcontrollers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combination thereof.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a first semiconductor structure, wherein the first semiconductor structure comprises an n-type channel, wherein the n-type channel comprises an oxide semiconductor; and a second semiconductor structure electrically coupled to the first semiconductor structure, wherein the second semiconductor structure comprises a p-type channel, wherein the p-type channel comprises a non-oxide semiconductor.

Example 2 includes the semiconductor device of Example 1, wherein the oxide semiconductor comprises oxygen and metal.

Example 3 includes the semiconductor device of any of Examples 1-2, wherein the oxide semiconductor comprises a perovskite.

Example 4 includes the semiconductor device of Example 3, wherein the perovskite comprises (i) barium, tin, and oxygen, (ii) strontium, tin, and oxygen, or (iii) strontium, titanium, and oxygen.

Example 5 includes the semiconductor device of any of Examples 3-4, wherein the perovskite comprises a lanthanide.

Example 6 includes the semiconductor device of Example 5, wherein the lanthanide comprises lanthanum.

Example 7 includes the semiconductor device of any of Examples 1-2, wherein the oxide semiconductor comprises indium and oxygen.

Example 8 includes the semiconductor device of any of Examples 1-7, wherein the non-oxide semiconductor comprises a group IV semiconductor or a group III-V semiconductor.

Example 9 includes the semiconductor device of Example 8, wherein: the non-oxide semiconductor comprises the group IV semiconductor, wherein the group IV semiconductor comprises silicon or germanium; or the non-oxide semiconductor comprises the group III-V semiconductor, wherein the group III-V semiconductor comprises (i) gallium and nitrogen, (ii) gallium and arsenic, or (iii) indium and phosphorous.

Example 10 includes the semiconductor device of any of Examples 1-9, wherein: the first semiconductor structure is an n-type metal-oxide-semiconductor (NMOS) transistor; the second semiconductor structure is a p-type metal-oxide-semiconductor (PMOS) transistor; and the semiconductor device further comprises complementary metal-oxide-semiconductor (CMOS) circuitry, wherein the CMOS circuitry comprises the NMOS transistor and the PMOS transistor.

Example 11 includes the semiconductor device of Example 10, wherein: the NMOS transistor further comprises a first source, a first drain, and a first gate, wherein the first source and the first drain are at opposite ends of the n-type channel, and wherein the first gate is around the n-type channel; and the PMOS transistor further comprises a second source, a second drain, and a second gate, wherein the second source and the second drain are at opposite ends of the p-type channel, and wherein the second gate is around the p-type channel.

Example 12 includes the semiconductor device of Example 11, wherein: the NMOS transistor further comprises a first ferroelectric layer between the first gate and the n-type channel; and the PMOS transistor further comprises a second ferroelectric layer between the second gate and the p-type channel.

Example 13 includes the semiconductor device of Example 12, wherein the PMOS transistor further comprises an oxide layer between the second ferroelectric layer and the p-type channel.

Example 14 includes the semiconductor device of any of Examples 10-13, wherein the NMOS transistor and the PMOS transistor are gate-all-around (GAA) transistors, ribbon field-effect transistors (FETs), ferroelectric FETs, or backend transistors.

Example 15 includes an electronic device, comprising: a plurality of transistors, wherein the respective transistors comprise a channel, wherein: the channel of at least one of the transistors is an n-type channel, wherein the n-type channel comprises an oxide semiconductor; and the channel of at least one of the transistors is a p-type channel, wherein the p-type channel comprises a group IV semiconductor or a group III-V semiconductor.

Example 16 includes the electronic device of Example 15, wherein the oxide semiconductor comprises a perovskite.

Example 17 includes the electronic device of Example 16, wherein the perovskite is doped with a lanthanide.

Example 18 includes the electronic device of any of Examples 15-17, wherein the respective transistors further comprise a source, a drain, and a gate, wherein the source and the drain are at opposite ends of the channel, and wherein the gate is over the channel.

Example 19 includes the electronic device of Example 18, wherein the respective transistors further comprise a ferroelectric layer between the gate and the channel.

Example 20 includes the electronic device of Example 19, wherein at least some of the respective transistors further comprise an oxide layer between the ferroelectric layer and the channel.

Example 21 includes the electronic device of any of Examples 15-20, wherein: the plurality of transistors include: an n-type metal-oxide-semiconductor (NMOS) transistor, wherein the NMOS transistor comprises the n-type channel; and a p-type metal-oxide-semiconductor (PMOS) transistor, wherein the PMOS transistor comprises the p-type channel; and the electronic device further comprises complementary metal-oxide-semiconductor (CMOS) circuitry, wherein the CMOS circuitry comprises the NMOS transistor and the PMOS transistor.

Example 22 includes the electronic device of any of Examples 15-21, further comprising: a circuit board; and an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.

Example 23 includes a system, comprising: complementary metal-oxide-semiconductor (CMOS) circuitry, wherein the CMOS circuitry comprises: one or more n-type transistors, wherein the respective n-type transistors comprise an oxide semiconductor channel; and one or more p-type transistors, wherein the respective p-type transistors comprise a non-oxide semiconductor channel; and an interconnect, wherein the n-type transistors and the p-type transistors are electrically coupled via the interconnect.

Example 24 includes the system of Example 23, wherein the n-type transistors and the p-type transistors are ferroelectric field-effect transistors.

1. A semiconductor device, comprising:
a first semiconductor structure, wherein the first semiconductor structure comprises an n-type channel, wherein the n-type channel comprises an oxide semiconductor; and
a second semiconductor structure electrically coupled to the first semiconductor structure, wherein the second semiconductor structure comprises a p-type channel, wherein the p-type channel comprises a non-oxide semiconductor.

2. The semiconductor device of claim 1, wherein the oxide semiconductor comprises a perovskite.

3. The semiconductor device of claim 2, wherein the perovskite comprises (i) barium, tin, and oxygen, (ii) strontium, tin, and oxygen, or (iii) strontium, titanium, and oxygen.

4. The semiconductor device of claim 3, wherein the perovskite further comprises a lanthanide.

5. The semiconductor device of claim 4, wherein the lanthanide comprises lanthanum.

6. The semiconductor device of claim 1, wherein the oxide semiconductor comprises indium and oxygen.

7. The semiconductor device of claim 1, wherein the non-oxide semiconductor comprises a group IV semiconductor or a group III-V semiconductor.

8. The semiconductor device of claim 7, wherein:
the non-oxide semiconductor comprises the group IV semiconductor, wherein the group IV semiconductor comprises silicon or germanium; or
the non-oxide semiconductor comprises the group III-V semiconductor, wherein the group III-V semiconductor comprises (i) gallium and nitrogen, (ii) gallium and arsenic, or (iii) indium and phosphorous.

9. The semiconductor device of claim 1, wherein:
the first semiconductor structure is an n-type metal-oxide-semiconductor (NMOS) transistor;
the second semiconductor structure is a p-type metal-oxide-semiconductor (PMOS) transistor; and
the semiconductor device further comprises complementary metal-oxide-semiconductor (CMOS) circuitry, wherein the CMOS circuitry comprises the NMOS transistor and the PMOS transistor.

10. The semiconductor device of claim 9, wherein:
the NMOS transistor further comprises a first source, a first drain, and a first gate, wherein the first source and the first drain are at opposite ends of the n-type channel, and wherein the first gate is around the n-type channel; and
the PMOS transistor further comprises a second source, a second drain, and a second gate, wherein the second source and the second drain are at opposite ends of the p-type channel, and wherein the second gate is around the p-type channel.

11. The semiconductor device of claim 10, wherein:
the NMOS transistor further comprises a first ferroelectric layer between the first gate and the n-type channel; and
the PMOS transistor further comprises a second ferroelectric layer between the second gate and the p-type channel.

12. The semiconductor device of claim 9, wherein the NMOS transistor and the PMOS transistor are gate-all-around (GAA) transistors, ribbon field-effect transistors (FETs), ferroelectric FETs, or backend transistors.

13. An electronic device, comprising:
a plurality of transistors, wherein the respective transistors comprise a channel, wherein:
the channel of at least one of the transistors is an n-type channel, wherein the n-type channel comprises an oxide semiconductor; and
the channel of at least one of the transistors is a p-type channel, wherein the p-type channel comprises a group IV semiconductor or a group III-V semiconductor.

14. The electronic device of claim 13, wherein the respective transistors further comprise a source, a drain, and a gate, wherein the source and the drain are at opposite ends of the channel, and wherein the gate is over the channel.

15. The electronic device of claim 14, wherein the respective transistors further comprise a ferroelectric layer between the gate and the channel.

16. The electronic device of claim 15, wherein at least some of the respective transistors further comprise an oxide layer between the ferroelectric layer and the channel.

17. The electronic device of claim 13, wherein:
the plurality of transistors include:
an n-type metal-oxide-semiconductor (NMOS) transistor, wherein the NMOS transistor comprises the n-type channel; and
a p-type metal-oxide-semiconductor (PMOS) transistor, wherein the PMOS transistor comprises the p-type channel; and
the electronic device further comprises complementary metal-oxide-semiconductor (CMOS) circuitry, wherein the CMOS circuitry comprises the NMOS transistor and the PMOS transistor.

18. The electronic device of claim 13, further comprising:
a circuit board; and
an integrated circuit coupled to the circuit board, wherein the integrated circuit comprises processing circuitry, memory circuitry, storage circuitry, or communication circuitry, wherein one or more of the transistors are comprised in the processing circuitry, the memory circuitry, the storage circuitry, or the communication circuitry.

19. A system, comprising:
complementary metal-oxide-semiconductor (CMOS) circuitry, wherein the CMOS circuitry comprises:
one or more n-type transistors, wherein the respective n-type transistors comprise an oxide semiconductor channel; and
one or more p-type transistors, wherein the respective p-type transistors comprise a non-oxide semiconductor channel; and
an interconnect, wherein the n-type transistors and the p-type transistors are electrically coupled via the interconnect.

20. The system of claim 19, wherein the n-type transistors and the p-type transistors are ferroelectric field-effect transistors.
